(19) United States
(12) Patent Application Publication
(10) Pub. No.: US 2025/0366354 A1
(43) Pub. Date: Nov. 27, 2025

(54) DISPLAY DEVICE

(71) Applicant: LG Display Co., Ltd., Seoul (KR)

(72) Inventors: Sung Gon HONG, Paju-si (KR); Jong Chan PARK, Paju-si (KR)

(73) Assignee: LG Display Co., Ltd., Seoul (KR)

(21) Appl. No.: 19/209,204

(22) Filed: May 15, 2025

(30) Foreign Application Priority Data
May 21, 2024 (KR) 10-2024-0065760

(51) Int. Cl. H10K 59/80; H10K 59/131; H10K 59/40; H10K 77/10

(52) U.S. Cl. CPC H10K 59/874; H10K 59/131; H10K 59/40; H10K 59/873; H10K 77/111

(57) ABSTRACT

A display device includes a substrate having a display area and a non-display area including a bending area. An encapsulation layer is positioned on the display area and the non-display area to protect internal components. An inner dam is in contact with the encapsulation layer in the non-display area to help control the flow of encapsulation materials. A touch member is positioned at least partially on the encapsulation layer and the inner dam, and includes a touch line, a touch insulating film, a touch planarization film, and a protective film positioned on the touch planarization film. An outer dam is in contact with the protective film of the touch member at an outer side of the inner dam, and have a first width. The touch planarization film is spaced apart from the outer dam between the outer dam and the bending area and have a second width greater than the first width.

### CROSS-REFERENCE TO RELATED APPLICATION

This application claims priority to and the benefit of Korean Patent Application No. 10-2024-0065760, filed May 21, 2024, the disclosure of which is incorporated herein by reference in its entirety.

### BACKGROUND

### Technical Field

The present disclosure relates to a display device and, more particularly, to a display device capable of improving reliability and durability.

### Description of Related Art

Display devices that display images on TVs, monitors, a desktop computer, a personal digital assistants (PDAs), smartphones, tablet PCs, laptops and so on are used in a variety of methods and forms.

The display devices include a display panel having a plurality of light-emitting elements, liquid crystals, plasma or the like for implementing an image and a transistor for controlling the operation of each light-emitting element, liquid crystal, plasma or the like and display the image to be displayed by the plurality of light-emitting elements, liquid crystals plasma or the like as it is.

A light-emitting display device having self-emitting elements may be implemented thinner than a display device having a built-in light source, and do not require a separate light source, making it possible to bend the display device or implement the display device in various designs.

The field of the display devices that visually display electrical information signals is developing rapidly with the advent of information age, and research is continuing on the performance development and sustainability of the display devices, such as a narrow bezel, low power consumption, and ensuring reliability for various display devices.

### BRIEF SUMMARY

The display device includes a dual dam structure and a layout that disperses mechanical stress, resulting in improved durability, reliability, and manufacturing efficiency. An inner dam contains an organic encapsulation layer, while an outer dam is positioned between the inner dam and a bending area. The outer dam is narrower than a nearby touch planarization film and is spaced apart to avoid direct contact. This arrangement helps absorb bending stress and reduces the likelihood of cracks forming near the bending region. First and second trenches formed on opposite sides of the outer dam expose an underlying inorganic touch insulating film, increasing surface energy difference and resistance to control the protective film's flow, and are filled with either the protective film or an optical member material to absorb mechanical stress.

Careful placement of materials and layers prevents damage from bending and reduces the impact of chemical residue, while maintaining effective barriers against moisture and oxygen. This design lowers defect rates and simplifies the fabrication process, which in turn helps reduce production costs and energy consumption.

Various embodiments of the present specification provide a display device capable of effectively controlling the flow of a protective film of a touch member by increasing surface energy difference or surface resistance, thereby reducing defect occurrence and improving durability.

Various embodiments of the present specification provide a display device that minimizes or prevents or at least reduces crack formation caused by chemical changes of an etchant or the like remaining during the process around a dam, and/or reduces stress caused by bending, thereby enhancing robustness and durability.

Various embodiments of the present specification provide a display device that minimizes or prevents or at least reduces crack formation by reducing stress concentration due to bending around a bending area and at a wire connection portion and/or prevents moisture or oxygen permeation, thereby improving reliability.

Various embodiments of the present specification provide a display device capable of reducing a product defect rate to lower manufacturing process cost, and shortening manufacturing process time, thereby reducing production energy consumption and greenhouse gas emissions.

A display device according to one embodiment of the present specification may include: a substrate having a display area and a non-display area including a bending area; an encapsulation layer positioned on the display area and the non-display area; an inner dam in contact with the encapsulation layer in the non-display area; a touch member positioned at least partially on the encapsulation layer and the inner dam, and including a touch line, a touch insulating film, a touch planarization film, and a protective film positioned on the touch planarization film; and an outer dam in contact with the protective film of the touch member at an outer side of the inner dam, and having a first width, wherein the touch planarization film is spaced apart from the outer dam between the outer dam and the bending area and has a second width greater than the first width.

The touch planarization film positioned between the outer dam and the bending area may be arranged to surround the outer dam and to overlap a connection portion for enabling the touch line adjacent to the bending area to be electrically connected beyond the bending area.

The display device according to one embodiment of the present specification may further include: a first trench formed by the touch planarization film between the outer dam and the inner dam being spaced apart from the outer dam, and a second trench formed by the touch planarization film between the outer dam and the bending area being spaced apart from the outer dam, wherein the first trench may be arranged on four sides of the non-display area surrounding the display area.

The first trench and the second trench may penetrate the touch planarization film to expose the touch insulating film positioned below the outer dam, and the touch insulating film may include an inorganic material.

The display device according to one embodiment of the present specification may further include: an optical member positioned on the touch member; and a coating layer positioned in the bending area, wherein the outer dam may overlap the optical member, and the touch planarization film positioned between the outer dam and the bending area may overlap the coating layer.

At least a portion of the first trench may be filled with the protective film of the touch member, and the second trench may be filled with at least a portion of the optical member.

The display device of the present specification may improve durability of the display device and/or reduce deformation or defect occurrence of the display device by effectively controlling the flow of the protective film of the touch member through an increase in surface energy difference or surface resistance by arranging a touch insulating film made of an inorganic material below the outer dam.

The display device according to the present specification may improve display quality by preventing or reducing chemical reactions caused by residual process materials or preventing or reducing cracks from spreading due to chemical reactions by filling the trench adjacent to the outer dam with a relatively thick protective film of the touch member or an organic material of the optical member.

The display device according to the present specification may absorb bending stress by arranging a relatively thick touch planarization film to overlap the wire connection portion including the touch line between the outer dam and the bending area, thereby preventing or reducing cracks in the films or wires around the bending area caused by bending stress and strain that may be concentrated in a stepped region around the bending area.

The display device according to the present specification may improve reliability of the display device by preventing or reducing bending stress from being transferred to a step-generation region caused by the outer dam by arranging the touch planarization film with a width greater than that of the outer dam between the outer dam and the bending area, thereby preventing or reducing crack formation due to bending.

The display device according to the present specification may reduce the manufacturing process cost and shorten the manufacturing process time due to the reduced defect rate, and may also reduce the production energy.

In addition, the display device according to one embodiment of the present specification may reduce the generation of the greenhouse gas that may occur due to the manufacturing process by optimizing the process, such as not increasing the manufacturing process, thereby implementing ESG (Environment/Social/Governance).

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view of a display device according to one exemplary embodiment;

FIG. 2 is one exemplary embodiment of a cross-sectional view taken along line I-I′ of FIG. 1;

FIG. 3 is a plan view of the display panel of FIG. 2 according to one exemplary embodiment;

FIG. 4 is a circuit diagram of a sub-pixel of FIG. 3 according to one exemplary embodiment;

FIG. 5 is an enlarged partial plan view of portion A of FIG. 3;

FIG. 6 is a cross-sectional view of a display device according to one exemplary embodiment in which an optical member of FIG. 2 is attached to a cross-sectional view taken along line II-II′ of FIG. 5;

FIG. 7 is an enlarged partial plan view of portion L of FIG. 6 according to one exemplary embodiment; and

FIG. 8 is an enlarged partial plan view of portion B of FIG. 5 according to another exemplary embodiment.

### DETAILED DESCRIPTION

Hereinafter, embodiments will be described with reference to the drawings.

The same reference numerals refer to the same components.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Herein, when a component (or region, layer, portion, etc.) is referred to as being “adhered,” “connected,” or “coupled” to another component, it is intended to mean that it may be directly adhered/connected/combined with the other component, or that a third component may be interposed between them.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” includes any one or more combinations that the associated configurations may define.

Terms such as “first,” “second,” and the like may be used to describe various components, but the components are not limited by such terms. These terms are used for the sole purpose of distinguishing one component from another. For example, without departing from the scope of the present embodiments, a first component may be referred to as a second component, and similarly, a second component may be referred to as a first component. Singular expressions include plural expressions unless the context clearly indicates otherwise.

The terms “on,” “under,” “beside,” “beneath,” “below,” “at the bottom,” “above,” “over,” “on the top,” and the like are used to describe the positional relationship of the configurations shown in the drawings. These terms are relative and are described with reference to the orientation shown in the drawings. For example, one or more other parts may be located between the two parts unless a term as “immediately” or “directly” is used. The spatially relative terms “on,” “under,” “beside,” “below,” “beneath,” “lower,” “above,” “upper,” “over,” and the like may be used to facilitate the description of the correlation between one element or component and another element or component, as shown in the drawings. The term spatially relative should be understood to include different orientations of the element in use or operation in addition to the orientations shown in the drawings. For example, an element described as “below” or “beneath” another element may be placed “above” another element if the elements shown in the drawings are reversed. Thus, the exemplary term “down” may include both down and up directions.

It should be understood that terms “include,” “comprise,” “contain,” or “have” are intended to specify the presence of features, numbers, steps, actions, components, parts, or combinations thereof described in the specification and not to exclude the presence or additional possibilities of one or more other features or numbers, steps, actions, components, parts, or combinations thereof.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

Each of the features of the various embodiments described herein may be combined with one another, in part or in whole, and are technically capable of various interlocking and operating arrangements, and each embodiment may be practiced independently of or in conjunction with one another.

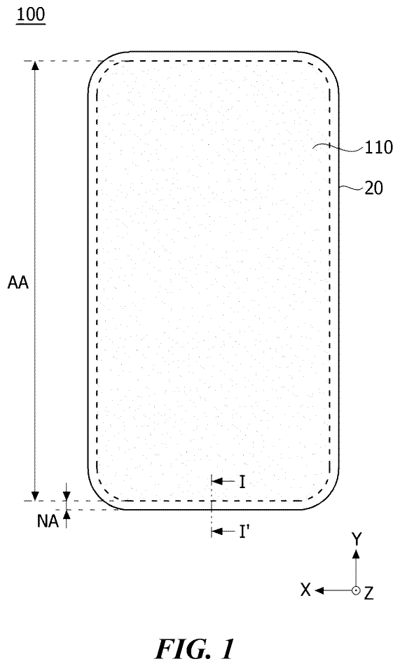

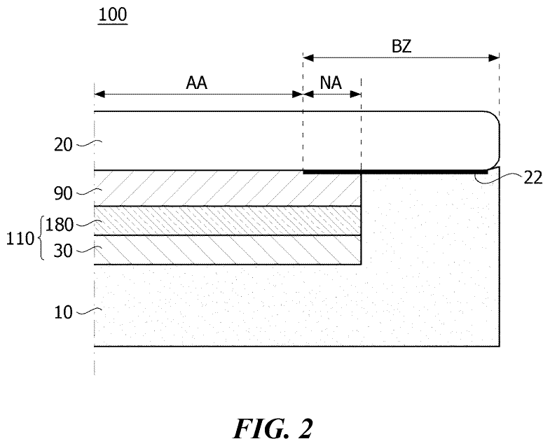

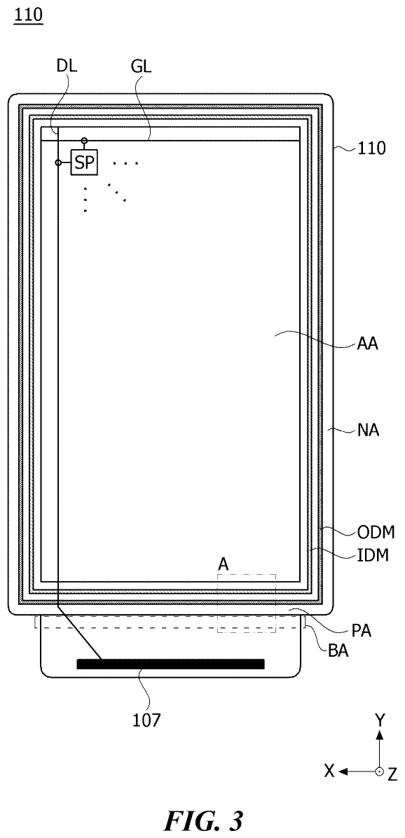

Hereinafter, a display device of the present specification will be described with reference to the accompanying drawings and embodiments as follows. FIG. 1 is a plan view of a display device according to one exemplary embodiment of the present specification, FIG. 2 is one exemplary embodiment of a cross-sectional view taken along the line I-I′ of FIG. 1, and FIG. 3 is a plan view of the display panel of FIG. 2, according to one exemplary embodiment.

Referring to FIGS. 1 and 2, a display device 100 according to an example of the present specification may include a display panel 110 including a display area AA and a non-display area NA, and an optical member 90 disposed on the display panel 110. The display device 100 may further include a bottom member 10 and a cover member 20 for protecting and supporting the display panel 110. The display panel 110 may include a panel 30 and a touch member 180.

The display area AA of the display device 100 may refer to an area that displays an image, and the area other than the display area AA may be referred to as the non-display area NA or a bezel area BZ in which no image is displayed. The bezel area BZ may be refer to an area in which the display area AA is obscured by the bottom member 10 and the cover member 20, which protect the display panel 110. The bezel area BZ may be the same size as the non-display area NA or larger in size than the non-display area NA.

The display area AA and the non-display area NA of the display device 100 may be equally applicable to the display panel 110. In FIG. 2, the non-display area NA and the bezel area BZ are illustrated based on the display panel 110 for ease of description, and the extent of the non-display area NA and the bezel area BZ is not limited to the illustration in FIG. 2. For example, the non-display area NA may have the same or larger size than the bezel area BZ.

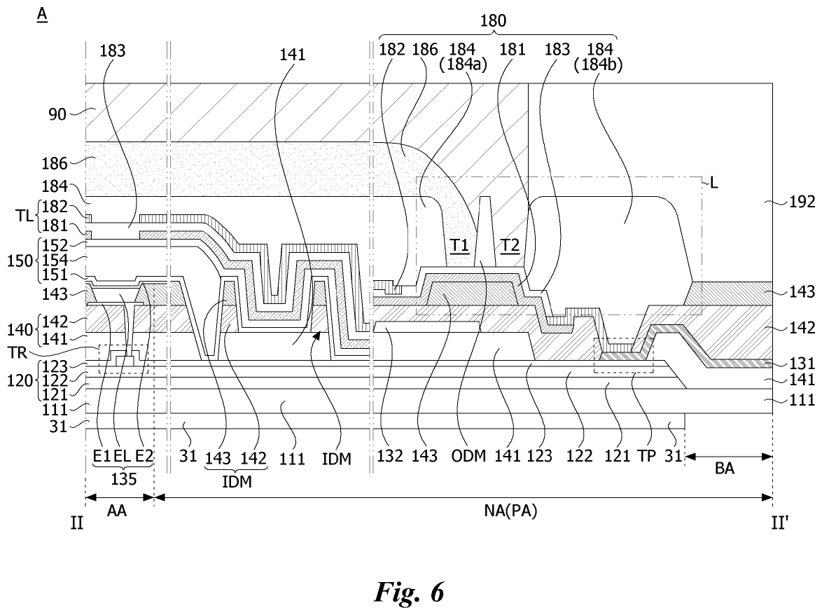

The bottom member 10 is disposed on the rear surface of the display panel 110 such that the lower portion of the display panel 110 maintains flat or level and provides additional rigidity. The bottom member 10 may be attached to the display panel 110 or to a structure on the rear surface of the display panel 110, such as a back plate 31 (see FIG. 6), using an adhesive or the like.

The bottom member 10 may be disposed to overlap the rear surface and the top and/or bottom, and/or left and/or right sides of the display panel 110. The bottom member 10 may be rigid, may have a flat surface, and may include a metallic material. The bottom member 10 may include a metallic material such as SUS (Steel Use Stainless). For example, the bottom member 10 may be a metal thin film or a metal plate, without limited thereto.

The bottom member 10 including a metallic material may minimize or prevent or at least reduce the occurrence of electromagnetic interference (EMI) of the display panel 110 and malfunction of the light-emitting element due to noise from batteries or semiconductor chips disposed on the rear surface of the bottom member 10 and attached to the display panel 110. The bottom member 10, which includes a metallic material, may also have a heat dissipation effect to dissipate heat and may function to protect the ground and the rear surface. The rigid bottom member 10 or the bottom member 10 made of a metallic material may protect the display panel 110 from external forces by increasing or reinforcing the rigidity.

The bottom member 10 may be disposed in a structure that overlaps or wraps around at least a portion of the side surfaces of the touch member 180 on the top and/or bottom, and/or left and/or right side surfaces of the display device 100. The bottom member 10 may be disposed in a structure that is combined with the cover member 20 at a side portion of the display panel 110.

The cover member 20 may be disposed on the upper portion of the display panel 110 to cover the front surface of the display panel 110, thereby protecting the display panel 110 from external impact. The edge portion of the cover member 20 may have a curvature portion or a curved surface that can be bent in the rear surface direction (−Z axis direction) of the display device 100. This allows the cover member 20 to be arranged to cover even the side areas of the display panel 110 disposed in the rear surface of the cover member 20, thereby protecting the display panel 110 from external impacts not only from the front surface of the display device 100, but also from the side surfaces of the display device 100.

The cover member 20 may be formed of a transparent material so as to overlap the area displaying the image. For example, the cover member 20 may be made of, but is not limited to, a transparent plastic material such as PMMA (polymethyl methacrylate), PC (polycarbonate), PET (polyethylene terephthalate), PP (polypropylene), etc., a tempered glass of a transparent glass material such as soda-lime glass, borosilicate glass and aluminum oxide silicate glass, a tempered plastic such as PC/ABS (Acrylonitrile Butadiene Styrene) based material, PC/SAN (Styrene-Acrylonitrile Copolymer) based material, PC/PBT (Polybutylene terephthalate) based material, PC/PP based material, PC/PMMA based material, etc., or the like capable of transmitting an image.

The display area AA and the non-display area NA may be applied to the cover member 20 in the same manner. An area through which an image is transmitted in the cover member 20 may be the display area AA. An area in the cover member 20 that surrounds the display area AA and through which an image is not transmitted may be a bezel area BZ including the non-display area NA. To improve the visibility of the image, a light shielding layer 22 containing a light shielding material such as ink, black dye, etc., may be disposed in the non-display area (NA).

The cover member 20 may be attached to the display panel 110 or to a structure that is disposed between the display panel 110 and the cover member 20. In one embodiment, the cover member 20 may be combined with the optical member 90 on the display panel 110.

The optical member 90 may be attached to an upper portion of the display panel 110 and may prevent or reduce reflection of external light to improve outdoor visibility and contrast ratio of the image displayed on the display panel 110. The optical member 90 may be disposed on the display area AA of the display panel 110 and may extend to the non-display area NA.

The optical member 90 may include a polarizer and a protective film protecting the polarizer (not shown). The optical member 90 may be configured in a form in which an adhesive material is disposed on the top surface and the rear surface of the polarizer, or it may be disposed in a form in which a polarizing material having flexibility and adhesion is coated on the display panel 110.

Referring to FIGS. 2 and 3, the display panel 110 includes a panel 30 and a touch member 180 disposed on the panel 30. The panel 30 may include the display area AA and the non-display area NA having a bending area BA.

A plurality of sub-pixels SP may be disposed in the display area AA of the panel 30, and an image may be displayed using the plurality of sub-pixels SP. An area in which the plurality of sub-pixels SP are disposed may be a display area AA, and an area other than the display area AA may be a non-display area NA.

The non-display area NA may include an edge area surrounding the display area AA that displays an image. The non-display area NA may be disposed along the perimeter of the display area AA, and the non-display area NA, including the bending area BA, may be a pad area PA.

The pad area PA may be an area in which structures for receiving external signals are disposed, and in which, for example, a drive integrated circuit (IC) 107 such as a data driver IC is disposed.

In the pad area PA, the bending area BA may be located in an area between the drive integrated circuit 107 and the display area AA. In at least one of the left and right regions of the panel 30 other than the pad area PA of the non-display area NA, at least one driver for driving a plurality of sub-pixels SP may be disposed. The driver may be a Gate-In-Panel (GIP). Various additional elements for driving pixels in the display area AA may also be disposed in the non-display area NA.

The non-display area NA may have an inner dam IDM and an outer dam ODM surrounding the display area AA. The outer dam ODM may be spaced apart from the inner dam IDM and located on the outside of the inner dam IDM. In other words, the outer dam is located closer to the edge of the panel than the inner dam IDM. As shown in FIG. 3, the inner dam IDM is between the display area AA and the outer dam ODM in a plan view of the display panel 110. Thus, the outer dam ODM is farther from the display area AA than the inner dam IDM. A detailed description of the inner dam IDM and the outer dam ODM will be described later.

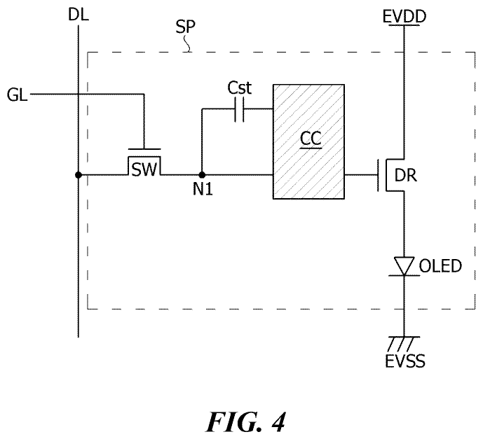

A plurality of sub-pixels SP in the display area AA of the panel 30 may be arranged, and at least one sub-pixel SP may include a switching transistor SW, a driving transistor DR, a capacitor Cst, a compensation circuit CC, and a light-emitting element (OLED) 135 (see FIG. 6), as shown in FIG. 4.

A first electrode (e.g., a drain electrode) of the switching transistor SW may be electrically connected to a data line DL, and a second electrode (e.g., a source electrode) of the switching transistor SW may be electrically connected to a first node N1. A gate electrode of the switching transistor SW may be electrically connected to a gate line GL. The switching transistor SW may transmit the data signal supplied through the data line DL to the first node N1 in response to a scan signal supplied through the gate line GL.

The capacitor Cst may be electrically connected to the first node N1 to charge a voltage applied to the first node N1. However, the present disclosure is not limited thereto.

A first electrode (e.g., drain electrode) of the driving transistor DR may receive a high potential driving voltage EVDD, and a second electrode (e.g., source electrode) of the driving transistor DR may be electrically connected to a first electrode (e.g., anode electrode) of the light-emitting element OLED. The driving transistor DR may control the amount of driving current flowing to the light-emitting element OLED in response to a voltage applied to the gate electrode of the driving transistor DR.

A semiconductor layer of the switching transistor SW and/or the driving transistor DR may include silicon, such as amorphous silicon (a-Si), polycrystalline silicon (poly-Si), low-temperature polycrystalline silicon (LTPS) or the like, or may include an oxide, such as indium-gallium-zinc-oxide (IGZO), indium-zinc-oxide (IZO), indium-gallium-oxide (IGO) or the like.

The light-emitting element OLED may output light corresponding to the driving current. The light-emitting element OLED may output light corresponding to any one of the following colors: red, green, blue, and white, and the colors are not limited thereto. As an exemplary alternative, the colors may also include cyan, magenta, yellow and black.

The light-emitting element OLED may include an anode electrode, a light emission layer disposed on the anode electrode, and a cathode electrode that supplies a common voltage. The light emission layer may be implemented to emit light of the same color, such as white light, for each pixel, or may be implemented to emit different colors, such as red, green, or blue light, for each sub-pixel SP., and the colors are not limited thereto

The light-emitting element OLED may be a top-emission type diodeor a bottom-emission type diode.

The compensation circuit CC may be provided in the sub-pixel SP to compensate for the threshold voltage of the driving transistor DR. The compensation circuit CC may include one or more transistors and capacitors, and may be configured in a variety of ways depending on the compensation method. The sub-pixel SP containing the compensation circuit CC may have various structures, such as 3T1C, 4T2C, 5T2C, 6T1C, 6T2C, 7T1C, and 7T2C, etc., without limited thereto.

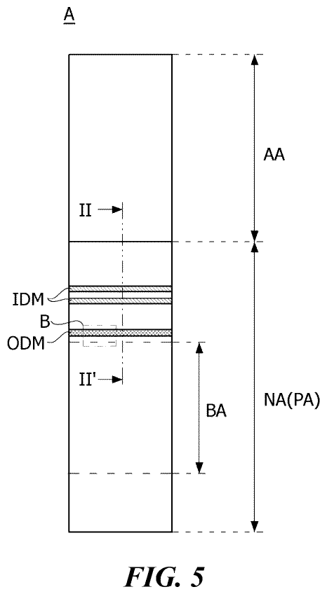

FIG. 5 is an enlarged partial plan view of an area A of FIG. 3, and FIG. 6 is one exemplary embodiment of a cross-sectional view in which the optical member 90 is combined with the cross-section view taken along the line II-II′ of FIG. 5. Referring to FIGS. 5 and 6, the panel 30 may include a substrate 111. An area on the substrate 111 may be divided into a display area AA and a non-display area NA. The display area AA and the non-display area NA on the substrate 111 may correspond to the display area AA and the non-display area NA on the display panel 110. Among the non-display areas NA, the non-display area NA having the pad area PA may include the bending area BA. The outer dam ODM may be disposed in the non-display area NA adjacent to the bending area BA, and the inner dam IDM may be disposed on the substrate 111 in the non-display area NA between the outer dam ODM and the display area AA.

The substrate 111 serves to support and protect the components of the display device 100 that are disposed on top of the substrate 111.

The substrate 111 may be formed of a plastic material that has flexible property. The substrate 111 may be formed by including polyimide (PI), polyethylene terephthalate (PET), polyester, polycarbonate (PC), polyethylene naphthalate (PEN), polyether ether ketone (PEEK), polyarylate (PAR), polycyclic olefin (PCO), polynorbornene, polyesthersulfone (PES), cyclooefin polymers (COP), or the like, and may include a flexible, thin-thickness glass material such as soda-calcium silicate, aluminosilicate, hard borate.

The substrate 111 may independently include a support substrate, such as a polyethylene terephthalate (PET), or polyimide film. The support substrate may have the same material as or a different material from the substrate 111. The substrate 111 may include an adhesive material, such as a pressure sensitive adhesive (PSA) or an optically clear adhesive (OCA) for bonding the PET and polyimide film. The adhesive material may be applied in the form of a film.

The substrate 111 may have a structure in which two layers including the above-described materials are stacked with an intermediate layer (not shown) interposed therebetween.

Referring to FIG. 6, a number of insulating films 120 may be stacked and disposed on the display area AA and the non-display area NA of the substrate 111. The insulating film 120 may include a first insulating film 121, a second insulating film 122, and a third insulating film 123. The number of insulating films 120 is not limited to three, and may be any integer larger than two.

The first insulating film 121 may be disposed on the display area AA and the non-display area NA on the substrate 111. The first insulating film 121 may be referred to as a buffer film and may function in the same manner as any buffer film known in the art. The first insulating film 121 may be disposed on the substrate 111 to protect the structures on the substrate 111 that are vulnerable to moisture or oxygen from moisture or oxygen penetration through the substrate 111 and to planarize the surface of the substrate 111.

The first insulating film 121 may be disposed on the bending area BA or extend until the bending area BA. The first insulating film 121 may be disposed so as to overlap the inner dam IDM and the outer dam ODM that are disposed in the outer portion of the substrate 111. The first insulating film 121 may be disposed up to an edge portion of the substrate 111 to prevent or reduce moisture or oxygen from penetrating from the edge of the substrate 111.

The first insulating film 121 may be a single inorganic film or may have a structure in which a plurality of inorganic films are stacked. For example, the first insulating film 121 may include one or more inorganic films selected from a silicon oxide film (SiOx), a silicon nitride film (SiNx), and a silicon oxynitride film (SiOxNy), or may include, for example, a multilayer film in which the above-described inorganic films are stacked.

A transistor TR may be disposed on the upper portion of the substrate 111 and may be the switching transistor SW or the driving transistor DR as described in FIG. 4 or any other transistor (not shown) that may be included in a subpixel. The transistor TR may include a gate electrode, a source electrode, a drain electrode, and an active layer. The transistor TR may be disposed on the first insulating film 121.

The gate electrode serves to turn-on or turn-off the transistor TR based on an electrical signal supplied externally through the gate line GL or the data line DL and may be composed of a single layer or a multilayer of a conductive metal such as, but not limited to, copper (Cu), aluminum (Al), molybdenum (Mo), chrome (Cr), gold (Au), titanium (Ti), nickel (Ni), tungsten (W), and neodymium (Nd), or alloys thereof.

The source electrode and the drain electrode may be composed of a single layer or a multilayer of a metallic material, including, but not limited to, copper (Cu), aluminum (Al), molybdenum (Mo), chrome (Cr), gold (Au), titanium (Ti), nickel (Ni), tungsten (W), and neodymium (Nd) or an alloy thereof, which are conductive metals.

The active layer may include a semiconductor material. The semiconductor material may be composed of a silicon-based semiconductor material such as amorphous silicon (a-Si) or polycrystalline silicon (poly-Si) or an oxide-based semiconductor material such as a metal oxide, e.g., indium gallium zinc oxide (IGZO), zinc oxide (ZnO), indium gallium oxide (IGO), indium zinc oxide (IZO), cadmium oxide (CdO), indium oxide (InO), zinc tin oxide (ZTO), zinc indium tin oxide (ZITO), indium gallium zinc tin oxide (IGZTO), and the like.

For ease of explanation, although the drawing illustrates the transistor TR connected to a light-emitting element 135 as an example among the various transistors TR constituting the display device 100, the same structure may be applied to other switching transistors SW and driving transistors DR and is not limited to the transistor TR connected to the light-emitting element 135. The transistor TR disposed in the display area AA may be a transistor TR including a silicon-based semiconductor material or a transistor TR including an oxide-based semiconductor material, depending on its function. Transistors TR including different semiconductor materials may be employed within a single sub-pixel SP.

The second insulating film 122 may be disposed on the first insulating film 121. The second insulating film 122 may be disposed in the display area AA to separate the transistors TR including different semiconductor materials (not shown) or to prevent or reduce a short circuit between their electrodes.

The second insulating film 122 may be disposed to extend to the non-display area NA and to overlap the inner dam IDM in the non-display area NA. The second insulating film 122 may include an inorganic film, such as a silicon oxide film (SiOx), a silicon nitride film (SiNx), a silicon oxynitride film (SiOxNy), or a multilayer film in which the above-described inorganic films are stacked.

The third insulating film 123 may be disposed on the second insulating film 122. The third insulating film 123 may be disposed in the display area AA to insulate between the electrodes constituting the transistor TR on the substrate 111 or to insulate the electrodes and the active layer. The third insulating film 123 may be referred to as an interlayer insulating film and may function in the same manner as any interlayer insulating film known in the art.

The third insulating film 123 may be disposed to extend to the non-display area NA and to overlap the inner dam IDM of the non-display area NA. The third insulating film 123 may include an inorganic material. The inorganic material may include, for example, one or more inorganic films of silicon oxide (SiOx), silicon nitride (SiNx), silicon oxynitride (SiOxNy), or a multilayer film in which the above-described inorganic films are stacked.

A driving circuit part, at least one signal line and power line may be disposed on the substrate 111 of the non-display area NA, and a description of these will be omitted in the present specification.

The organic film 140 may be disposed on the transistor TR to protect the transistor TR and mitigate a step difference caused by the transistor TR. The organic film 140 may be disposed between the structures or the elements of the transistor TR and the light-emitting element 135 to reduce the parasitic capacitance generated between the transistor TR and the light-emitting element 135. The organic film 140 may be disposed on the insulating film 120 to provide a planarized surface, so it may be also called planarization layer.

The organic film 140 may be a film in which a film made of an organic material is formed of a single layer or a multilayer. The organic film 140 may include a first organic film 141 and a second organic film 142 on the first organic film 141.

The first organic film 141 may cover the transistor TR in the display area AA to planarize the upper surface of the transistor TR, and planarize the upper surface of the non-display area NA.

The first organic film 141 may be disposed to extend up to the non-display area NA. The first organic film 141 may be disposed to overlap the inner dam IDM and outer dam ODM of the non-display area NA. The first organic film 141 may be disposed to overlap the bending area BA.

The first organic film 141 may include a contact hole in the non-display area NA for supplying signals or the like to lines or electrodes on the display area AA. For example, the first organic film 141 may have a contact hole that exposes a connection wire 131 disposed in the non-display area NA to supply signals to a first touch line 181 and a second touch line 182 that constitute the touch member 180 on the display area AA.

The first organic film 141 may include an organic material. The organic material may include one or more materials of acrylic resin, phenolic resin, polyimide resin, unsaturated polyester resin, polyamide resin, benzocyclobutene, polyphenylene resin, and polyphenylene sulfide resin, without limited thereto.

The first organic film 141 may be disposed as a composite stack of an inorganic insulating material film and an organic insulating material film.

The second organic film 142 may be disposed on the first organic film 141.

The second organic film 142 may be cover the transistor TR and the first organic film 141 in the display area AA and the non-display area NA to planarize their upper surface. The second organic film 142 may be disposed on the first organic film 141 in the display area AA to extend to the non-display area NA.

The second organic film 142 may constitute a part of the inner dam IDM in the non-display area NA, and may be arranged below the outer dam ODM to overlap the outer dam ODM. The second organic film 142 may be arranged to overlap the bending area BA. In this case, the connection wire 131 may be positioned between the first organic film 141 and the second organic film 142 in the bending area BA. In addition, a metal layer 132 may be positioned between the first organic film 141 and the second organic film 142 in a non-bending area of the non-display area NA other than the bending area BA. The metal layer 132 may include the same material as the connection wire 131, and the outer end of the metal layer 132 may overlap the outer dam ODM.

The second organic film 142 may be arranged in the non-display area NA to overlap the contact hole of the first organic film 141. The second organic film 142 may have a contact hole in a region in which a layer positioned below the first organic film 141 is exposed by the first organic film 141. For example, in order to supply signals to the first touch line 181 and the second touch line 182 constituting the touch member 180 in the display area AA, the second organic film 142 may have a contact hole that exposes a partial region of the connection wire 131 positioned in the non-display area NA. The first touch line 181 and the second touch line 182 constituting the touch member 180 may be connected to the connection wire 131 through the contact hole of the second organic film 142 in the non-display area NA.

The second organic film 142 may be disposed on the planarized upper surface of the first organic film 141 in the non-displayed area NA so as to constitute a portion of the inner dam IDM. A width of the bottom surface of the second organic film 142, which constitutes the inner dam IDM, is smaller than a width of the top surface of the first organic film 141.

The second organic film 142 may include an organic material. The organic material may include one or more materials of acrylic resin, phenolic resin, polyimide resin, unsaturated polyester resin, polyamide resin, benzocyclobutene, polyphenylene resin, and polyphenylene sulfide resin, without limited thereto.

The second organic film 142 may be disposed as a composite stack of an inorganic insulating material film and an organic insulating material film.

In addition to the insulating film 120 described above, organic films or inorganic films having various functions may be further disposed between the substrate 111 and the organic film 140.

The light-emitting element 135 may be disposed on the organic film 140 of the display area AA. The light-emitting element 135 may be electrically connected to the transistor TR through the organic film 140. The light-emitting element 135 may include a first electrode E1, a light emission layer EL, and a second electrode E2.

The first electrode E1 may function as an anode. The first electrode E1 may be connected to the transistor TR by passing through the organic film 140.

The first electrode E1 may include a metallic material having high reflectivity. For example, the first electrode E1 may be formed of a multilayer structure, such as a stacked structure (Ti/Al/Ti) of aluminum (Al) and titanium (Ti), a stacked structure (ITO/AI/ITO) of aluminum (Al) and ITO, and a stacked structure (ITO/APC/ITO) of an APC (Ag/Pd/Cu) alloy and ITO, or a stacked structure (Ag/MoTI) of silver (Ag) and molybdenum/titanium alloy, or it may include a single layer structure made of any one material or an alloy of two or more materials selected from silver (Ag), aluminum (Al), molybdenum (Mo), gold (Au), magnesium (Mg), calcium (Ca), or barium (Ba), without limited thereto. The first electrode E1 may be referred to as a reflective electrode.

The light emission layer EL may be provided on the first electrode E1. The light emission layer EL may include a hole injection layer, a hole transport layer, an organic light emission layer, an electron transport layer, and an electron injection layer, without limited thereto. For example, in the light emission layer EL, some layers may be omitted, and some layers can be combined with each other.

When a voltage is applied to the first electrode E1 and the second electrode E2, holes and electrons may be transferred to the organic light emission layer through the hole injection layer and the hole transport layer and the electron injection layer and the electron transport layer, respectively, and may combine with each other in the organic light emission layer to emit light.

Although the drawing shows that the light emission layer EL is disposed in an opening area, the hole injection layer, the hole transport layer, the electron transport layer, and the electron injection layer constituting the light-emission layer EL may commonly be disposed in front of the display area AA.

The light emission layer EL may include a red light emission layer that emits red light, a green light emission layer that emits green light, and a blue light emission layer that emits blue light. The red light emission layer, the green light emission layer, and the blue light emission layer may be disposed on the first electrode E1 for each sub-pixel SP. The red light emission layer may be patterned and disposed in the red sub-pixel, the green light emission layer may be patterned and disposed in the green sub-pixel, and the blue light emission layer may be patterned and disposed in the blue sub-pixel, but is not necessarily limited thereto, and at least two or more organic light emission layers among the red light emission layer, the green light emission layer, and the blue light emission layer may be stacked and disposed in one sub-pixel SP. Colors are not limited to red, blue and green. Other color system may also be adopted such as CMYK.

The light emission layer EL may be a white light emission layer that emits white light. In this case, the organic light emission layer of the light emission layer EL may be a common layer commonly disposed rather than patterned in the sub-pixels SP.

As previously described, the light emission layer EL may be arranged in a tandem structure of two or more stacks. In this case, each of the light-emitting elements 135 may include a charge generating layer disposed between the stacks. The charge generating layer may be a common layer disposed on the front surface of the display area AA.

The second electrode E2 may be provided on the light emission layer EL. The second electrode E2 may function as a cathode. The second electrode E2 may be disposed not only in the emission area of the sub-pixel SP but also in the whole area of the display area AA. The second electrode E2 may be disposed in a patterned manner if the display area AA is functionally divided.

The second electrode E2 may be a common layer that is commonly disposed in the sub-pixels SP and applied with the same voltage. To this end, the second electrode E2 may be disposed in the display area AA to extend up to a portion of the non-display area NA.

The second electrode E2 may be a light-transmissive electrode. The second electrode E2 may include a transparent conductive material (TCO, Transparent Conductive Material), such as ITO, IZO, IGO, IGZO, IZTO, or the like, which may transmit light, or a semi-transmissive conductive material, such as magnesium (Mg), silver (Ag), or an alloy of magnesium (Mg) and silver (Ag). When the second electrode E2 includes a semi-transmissive conductive material, the light emission efficiency may be increased by the micro-cavity.

In the above, the top-emission type has been described as an example of the light-emitting element 135. However, the light-emitting element 135 of the present specification is not limited thereto and may be of the bottom-emission type in which light emitted from the light emission layer EL is emitted toward the substrate 111. In this case, the first electrode E1 may be composed of a transparent or translucent electrode material, and the second electrode E2 may be composed of a reflective electrode material. The materials described above may be applied as the transparent and translucent electrode material and the reflective electrode material.

A third organic film 143 may be disposed on the second organic film 142 to cover an end of the first electrode E1 of the light-emitting element 135.

The third organic film 143 may be referred to as a bank defining the emission area. The third organic film 143 may be disposed to ensure that the first electrodes E1 between adjacent sub-pixels SP are electrically insulated therebetween while opening the first electrode E1 of the emission area for each sub-pixel. The third organic film 143 may be disposed to function as a spacer as well as a bank by using a halftone mask.

The third organic film 143 may be disposed in the display area AA to extend up to a portion of the non-display area NA. The third organic film 143 may be disposed in a patterned manner in the non-display area NA depending on the function of the area.

The third organic film 143 may be disposed on the second organic film 142 in the non-displayed area NA to constitute a portion of the inner dam IDM. The third organic film 143 may be disposed under the outer dam ODM to overlap the outer dam ODM. The third organic film 143 may be disposed on the second organic film 142 of the bending area BA to overlap the bending area BA.

The inner dam IDM and the outer dam ODM are made of different materials.

The inner dam IDM and the outer dam ODM are located on different layers.

The inner dam IDM may be made of multiple different materials and may include different layers.

Multiple inner dams might be arranged.

The outer dam ODM is made of a single material.

The third organic film 143 may include one organic material selected from polyimide resin, acrylic resin, epoxy resin, phenolic resin, and polyamide resin, without limited thereto.

An encapsulation layer 150 may be disposed on the light-emitting element 135. The encapsulation layer 150 may be disposed on the display area AA and the non-display area NA. The encapsulation layer 150 may cover the display area AA and the non-display area NA to prevent or reduce oxygen or moisture from penetrating into structures on the substrate 111, such as the light-emitting element 135 and the transistor TR. Other layers, such as a capping layer, may also be interposed between the encapsulation layer 150 and the second electrode E2 as desired.

The encapsulation layer 150 may be composed of a plurality of layers. The encapsulation layer 150 may be made of a structure in which organic films and inorganic films are alternately stacked. The encapsulation layer 150 according to one embodiment of the present specification may include a first encapsulation layer 151, a second encapsulation layer 152, and an organic encapsulation layer 154 disposed between the first encapsulation layer 151 and the second encapsulation layer 152. The first and second encapsulation layers 151 and 152 may be inorganic encapsulation films. The first encapsulation layer 151 may be disposed adjacent to the light-emitting element 135, and the second encapsulation layer 152 may be disposed at the uppermost end of the encapsulation layer 150.

The first encapsulation layer 151 constituting the encapsulation layer 150 may be disposed in the display area AA and the non-display area NA on the substrate 111. The first encapsulation layer 151 may be disposed on the upper surface of the transistor TR and the light-emitting element 135 of the display area AA. The first encapsulation layer 151 may completely cover the light-emitting element 135 to seal the light-emitting element 135.

The first encapsulation layer 151 may be disposed to extend up to a portion of the non-display area NA. The first encapsulation layer 151 may be disposed to overlap at least one inner dam IDM in the non-display area NA. The first encapsulation layer 151 may cover and/or directly contact the inner dam IDM and may be disposed to extend toward the bending area BA. The first encapsulation layer 151 may not overlap the outer dam ODM adjacent to the bending area BA and may not be disposed in the bending area BA.

The first encapsulation layer 151 may be made of an inorganic insulating material. For example, the first encapsulation layer 151 may include silicon oxide, silicon nitride, and/or silicon oxynitride, which are examples of inorganic insulating materials.

An organic encapsulation layer 154 may be disposed on the first encapsulation layer 151, and the organic encapsulation layer 154 may function to planarize the upper surface so as to minimize or prevent or at least reduce cracking that may occur due to step coverage by the structures under the organic encapsulation layer 154.

The organic encapsulation layer 154 may include one or more organic materials selected from the group consisting of polyethylene terephthalate, polyethylene naphthalate, polycarbonate, polyimide, polyethylene sulfonate, polyoxymethylene, polyarylate, and hexamethyldisiloxane, without limited thereto.

The organic encapsulation layer 154 may be made of an organic material and it may flow in a liquid state during the manufacturing process, and the inner dam IDM may be disposed in the non-display area NA at the outer portion of the display area AA to control the flow of the organic encapsulation layer 154. IN other words the organic encapsulation layer 154 only flows until a first inner side surface of the most inner dam IDM. On top or on the upper surface of the first inner dam IDM the first and second inorganic encapsulation layers 151, 152 are in direct contact.

The inner dam IDM may be disposed in the non-display area NA in such a way that it surrounds the display area AA. The inner dam IDM may be in contact with the encapsulation layer 150 in the non-display area NA. One or more inner dams IDM may be disposed or a number of inner dams IDM may be disposed to be spaced apart from each other, and the first organic film 141 may be disposed to be exposed in a space where a number of inner dams IDM are spaced apart from each other. When there is a plurality of inner dams IDM, a portion of the encapsulation layer 150 may be disposed between the plurality of inner dams IDM.

The inner dam IDM may be disposed in an embossed structure on the substrate 111, and may be disposed to include the second organic film 142 and the third organic film 143 on the first organic film 141 in the non-display area NA.

The first encapsulation layer 151 and the second encapsulation layer 152 may be combined on the inside surface of the inner dam IDM or on the upper surface of the inner dam IDM to trap the organic encapsulation layer 154 disposed between the first encapsulation layer 151 and the second encapsulation layer 152 inside the inner dam IDM. The combined structure of the first encapsulation layer 151 and the second encapsulation layer 152, or the second encapsulation layer 152, may be disposed to extend onto the substrate 111 at the outer portion of the inner dam IDM along the outside of the inner dam IDM.

As used herein, the inside refers to the side facing the display area AA with respect to the corresponding structure, and the outside refers to the side facing the edge of the display panel 110 with respect to the corresponding structure.

In one example, the combined structure of the first encapsulation layer 151 and the second encapsulation layer 152 or the second encapsulation layer 152 may be disposed to extend toward the bending area BA. The combined structure of the first encapsulation layer 151 and the second encapsulation layer 152 or the second encapsulation layer 152 may not overlap the outer dam ODM adjacent to the bending area BA and may not be disposed in the bending area BA. The encapsulation layer 150 may be disposed on the inner dam IDM and the touch member 180 may be disposed on the encapsulation layer 150 to overlap the inner dam IDM. The touch member 180 may be disposed on the inner dam IDM with the encapsulation layer 150 therebetween.

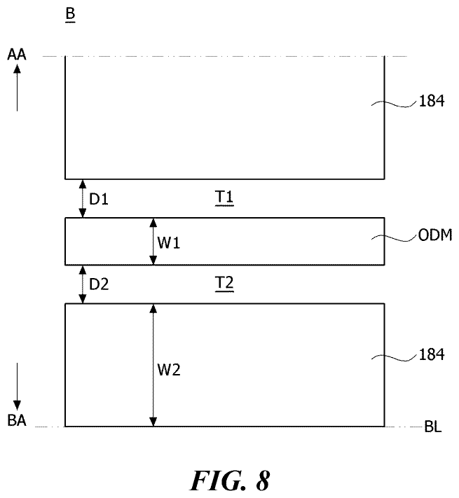

Because the flow to the outside of the organic encapsulation layer 154 is controlled by the inner dam IDM, the organic encapsulation layer 154 may be in contact with the inner dam IDM, but may not be in contact with the outer dam ODM disposed on the outside of the inner dam IDM. The organic encapsulation layer 154 may be arranged so as to not overlap and not in contact with the touch planarization film 184 disposed adjacent to the bending line (BL; see FIG. 8). Here, the outer side of the inner dam IDM may be a side facing the edge of the display device.

The second encapsulation layer 152 may be disposed on the organic encapsulation layer 154.

The second encapsulation layer 152 may be in contact with or combined with the lower first encapsulation layer 151 in an area where the inner dam IDM is disposed, and may be disposed to cover the organic encapsulation layer 154. The second encapsulation layer 152 may completely cover the organic encapsulation layer 154 disposed in the display area AA and the non-display area NA. The second encapsulation layer 152 may be combined with the first encapsulation layer 151 in an area where the inner dam IDM is disposed, so that the organic encapsulation layer 154 may not be exposed to the outside.

The second encapsulation layer 152 may be disposed to extend up to the end of the substrate 111, but may not be disposed in the bending area BA. The second encapsulation layer 152 may be disposed up to the inside of the bending area BA in the non-display area NA having the pad area PA, and may be disposed up to the end of the substrate 111 in the other non-display area NA.

In this way, the lower first encapsulation layer 151 and the uppermost second encapsulation layer 152 constituting the encapsulation layer 150 are combined on the side surface of the inner dam IDM, and the organic encapsulation layer 154 is trapped inside the inner dam IDM, which may prevent or reduce moisture or oxygen from penetrating from the outside and/or prevent or reduce the occurrence of cracking due to moisture or oxygen penetration, thereby preventing or reducing the deformation of the panel 30.

The second encapsulation layer 152 may be made of an inorganic insulating material. For example, the second encapsulation layer 152 may include silicon oxide, silicon nitride, and/or silicon oxynitride, which are examples of inorganic insulating materials.

A touch member 180 may be disposed on the encapsulation layer 150. The touch member 180 may be disposed between the optical member 90 and the panel 30, and the touch member 180 may be disposed directly on the encapsulation layer 150. In this case, as shown in FIG. 2, the optical member 90 is disposed on the upper portion of the touch member 180.

The touch member 180 may be disposed in a position corresponding to the display area AA of the panel 30, and the touch member 180 may be disposed to extend up to the non-display area NA outside of the encapsulation layer 150 and the inner dam IDM. The touch member 180 may be disposed to correspond to the panel 30 until before the bending area BA.

The touch member 180 may include a first touch line 181, a second touch line 182, a touch planarization film 184, and a protective film 186. The touch member 180 may further include a touch insulation film 183 disposed between the first touch line 181 and the second touch line 182 to insulate them.

The first touch line 181 may be disposed on the encapsulation layer 150. The first touch line 181 may be disposed on the second encapsulation layer 152 to correspond to the display area AA and the non-display area NA. Although only briefly illustrated, the first touch line 181 disposed to correspond to the display area AA and the non-display area NA may be formed with a single conductive film extending therefrom, or may be formed with multiple conductive films disposed and connected in different layers.

The first touch line 181 may be disposed in a non-emission area other than the emission area in the display area AA, which is opened by the third organic film 143, to prevent or reduce the luminance and light transmittance of the emission area from deteriorating.

The first touch line 181 may be disposed in a mesh shape in a non-emission area. The inside of the mesh shape may be a rhombus or a rectangle or any other suitable shape. The emission area may correspond to the sub-pixel SP. The first touch line 181 may be disposed to overlap the third organic film 143 in the non-emitting area in the display area AA.

The first touch line 181 may be disposed up to an area beyond the encapsulation layer 150. The first touch line 181 may cover the inner dam IDM in the non-display area NA and may be disposed up to an area adjacent to the outer dam ODM outside the inner dam IDM.

The first touch line 181 may be disposed using an opaque conductive material having a low material resistivity. The first touch line 181 may be disposed as a single layer or a multilayer made of any one of molybdenum (Mo), copper (Cu), titanium (Ti), aluminum (Al), chrome (Cr), gold (Au), nickel (Ni), neodymium (Nd), tungsten (W), or an alloy thereof.

In the display area AA, the second touch line 182 may be positioned on the first touch line 181 with the touch insulating film 183 interposed therebetween to be insulated from the first touch line 181.

The second touch line 182 may be positioned above the second encapsulation layer 152 to correspond to the display area AA and the non-display area NA. Although briefly illustrated in the drawing, the second touch line 182 positioned to correspond to the display area AA and the non-display area NA may be formed either by extending a single conductive film or by arranging and connecting a plurality of conductive films across different layers. For example, in the non-display area NA, the second touch line 182 may be electrically connected to the same metal layer as the first touch line 181 of the display area AA to supply or receive a signal.

The second touch line 182 may be positioned in the non-emission area excluding the emission area opened by the third organic film 143 in the display area AA to prevent or reduce a decrease in the luminance and transmittance of the emission area. The second touch line 182 may be arranged to overlap the third organic film 143 of the non-emission area in the display area AA.

The second touch line 182 may be arranged in a mesh shape in the non-emission area of the display area AA. The interior of the mesh shape may have a rhombus or a quadrilateral shape or any other suitable shape. The emission area may correspond to the sub-pixel SP. The second touch line 182 may extend to a region beyond the encapsulation layer 150.

The second touch line 182 may extend to a region adjacent to the outer dam ODM positioned at the outer side of the inner dam IDM while covering the inner dam IDM in the non-display area NA. The second touch line 182 may be connected to the connection wire 131 in a region before the bending area BA and may be connected to a touch driver (not shown) beyond the bending area BA through the connection wire 131 of the bending area BA.

The second touch line 182 may be connected to the connection wire 131 of the bending area BA to prevent or reduce cracks in the wire due to bending. A connection portion TP between the second touch line 182 and the connection wire 131 may be positioned between the outer dam ODM and the inner boundary of the bending area BA.

In the present specification, “inner” denotes a direction toward the display area AA, and “outer” denotes a direction opposite to inner. The inner boundary of the bending area BA refers to an edge of a region in a direction toward the display area AA, and the outer boundary of the bending area BA refers to an edge of a region in a direction toward a trimming line of the substrate 111 or the display panel 110.

The connection portion TP between the second touch line 182 and the connection wire 131 may be positioned on the third insulating film 123, and may be a region where both the first organic film 141 and the second organic film 142 have been removed. For example, the second touch line 182 may be connected, through the contact hole of the second organic film 142, to the connection wire 131 positioned on the first organic film 141 and also positioned on the third insulating film 123 through the contact hole of the first organic film 141.

In the drawing, by way of example, the second touch line 182 is shown as being connected to the connection wire 131 of the bending area BA and extending beyond the bending area BA, but this is merely for explaining the path of a touch signal. Although not shown in the drawing, a stacked structure including a structure in the connection portion TP may also be applied to the first touch line 181 in the same or similar manner.

For example, the first touch line 181 may be connected to the connection wire 131 between the inner dam IDM and the outer dam ODM, and may be connected to the touch driver (not shown) beyond the bending area BA through the connection wire 131 of the bending area BA.

The second touch line 182 may be formed using an opaque conductive material having low resistance. The second touch line 182 may be arranged as a single layer or multiple layers made of any one of molybdenum (Mo), copper (Cu), titanium (Ti), aluminum (Al), chromium (Cr), gold (Au), nickel (Ni), neodymium (Nd), tungsten (W), or an alloy thereof.

For example, the first touch line 181 and the second touch line 182 may have a three-layer structure of titanium (Ti)/aluminum (Al)/titanium (Ti) made of a conductive metal material, but is not limited thereto.

The touch member 180 may further include the connection wire 131 connected to the first touch line 181 or the second touch line 182 and extending to the bending area BA.

The connection portion TP, where the first touch line 181 or the second touch line 182 is connected to the connection wire 131, may be positioned at the inner side of the bending area BA adjacent to the bending area BA to prevent or reduce crack formation when the display panel 110 is bent. The connection portion TP may be positioned between the outer dam ODM and the bending area BA.

The connection portion TP may overlap the touch planarization film 184, and the stepped shape of the connection portion TP may be planarized by the touch planarization film 184.

The connection wire 131 may extend to the outer side of the bending area BA and may be connected to the touch driver (not shown) in the pad area PA of the non-display area NA, allowing the first touch line 181 or the second touch line 182 to be connected to the touch driver (not shown) beyond the outer side of the bending area BA.

The connection wire 131 positioned in the non-display area NA may include the same material as the material of one electrode constituting the transistor TR of the display area AA or may be positioned in the same layer as one electrode constituting the transistor TR of the display area AA.

The touch planarization film 184 may be positioned on the first touch line 181 and the second touch line 182. The touch planarization film 184 may cover the stepped portions or irregularities of the structures, including the first touch line 181 and the second touch line 182, positioned below the touch planarization film 184, and provide a flat top surface.

The touch planarization film 184 may be positioned in a region where the first touch line 181 or the second touch line 182 is positioned. Specifically, the touch planarization film 184 may be arranged over the entire display area AA, and arranged to cover the inner dam IDM of the non-display area NA and to expose the organic film positioned below the touch planarization film 184 in the bending area BA. For example, the touch planarization film 184 may be arranged to expose the third organic film 143 of the bending area BA in the non-display area NA.

The touch planarization film 184 may be arranged at the outer side of the outer dam ODM so as to be adjacent to a boundary portion of the bending area BA in the non-display area NA. Here, the boundary portion refers to a peripheral region including a bending line BL (see FIG. 8) that defines the bending area BA.

The touch planarization film 184 may be arranged to overlap the connection portion TP at the inner side of the bending area BA without overlapping the outer dam ODM. An inner groove of the connection portion TP may be filled with the touch planarization film 184.

The touch planarization film 184 may cover electrodes, e.g., the first touch line 181 and the second touch line 182, positioned below the touch planarization film 184 to block moisture and oxygen from entering the interior from the outside and/or to prevent or reduce corrosion of the first touch line 181 and the second touch line 182.

The touch planarization film 184 positioned between the outer dam ODM and the bending area BA may not only cover the first touch line 181 or the second touch line 182 of the connection portion TP but also fill the groove on the connection portion TP to prevent or reduce bending stress transferred from the adjacent bending area BA from being concentrated, thereby reducing preventing or cracks.

The touch planarization film 184 positioned adjacent to the bending line BL between the outer dam ODM and the bending area BA may be arranged not to contact with the organic encapsulation layer 154 of the encapsulation layer 150 and not to overlap the protective film 186 of the touch member 180.

The touch planarization film 184 may include an organic material. The organic material constituting the touch planarization film 184 may include, for example, a polymer such as silicon oxycarbon (SiOCz), epoxy, polyimide, polyethylene, or acrylate-based material, but is not limited thereto. The touch planarization film 184 may include the same material as the outer dam ODM.

The protective film 186 may be positioned on the touch planarization film 184. The protective film 186 may additionally planarize a region that is not partially planarized by the touch planarization film 184.

The protective film 186 may be arranged over the entire display area AA to cover the touch planarization film 184. The protective film 186 may be arranged to cover the first touch line 181 and the second touch line 182 positioned in the display area AA and the non-display area NA. The protective film 186 may cover the touch planarization film 184 covering the inner dam IDM in the non-display area NA, and the organic film positioned below the touch planarization film 184 may be arranged to be exposed in the bending area BA.

For example, the protective film 186 may be arranged to expose the third organic film 143 of the bending area BA in the non-display area NA. The protective film 186 may be arranged in the non-display area NA adjacent to the bending area BA such that it does not overlap the connection portion TP but overlaps at least a portion of the outer dam ODM or contact a side surface of the outer dam ODM.

Moisture and oxygen that may enter from the outside of the display device 100 may be additionally blocked by the protective film 186.

The protective film 186 may include an organic material. The organic material may be, for example, a polymer such as silicon oxycarbon (SiOCz), epoxy, polyimide, polyethylene, or acrylate-based material, but is not limited thereto. The protective film 186 may have thermosetting properties or photocurable properties that allow it to be cured by heat or light. For example, the protective film 186 may have ultraviolet curable properties including a photoinitiator that initiates a polymerization reaction by receiving ultraviolet rays.

The protective film 186 may be arranged in various ways such as inkjet coating or slit coating. For example, the protective film 186 may be arranged by spraying or dropping a liquid organic material onto the display area AA using an inkjet device or a nozzle coating device on the substrate 111 on which the touch planarization film 184 is positioned. As the spray nozzle moves over the coating area (or as a target object moves while the nozzle remains fixed), the protective film 186, which is composed of an organic material in a flow state, may be positioned in the coating area.

The protective film 186, made of an organic material, may be in a high-density liquid-like state until cured, and may spread toward the bending area BA of the non-display area NA. In order to control the flow of the protective film 186 that may spread toward the bending area BA, the outer dam ODM is positioned adjacent to the bending area BA in the non-display area NA.

The outer dam ODM may be positioned between the inner dam IDM and the bending area BA. The outer dam ODM may be positioned to be in contact with the protective film 186 of the touch member 180 in the non-display area NA to control the flow of the protective film 186. The protective film 186 of the touch member 180 may be in contact with the inner side surface of the outer dam ODM. The outer dam ODM may surround the inner dam IDM (see FIG. 3) and may be arranged to be in contact with four sides of the protective film 186 of the touch member 180 in the non-display area NA.

The outer dam ODM may be arranged between the bending area BA and the inner dam IDM, and the touch planarization film 184 may be arranged between the outer dam ODM and the bending area BA while being spaced apart from the outer dam ODM, and the touch planarization film 184 may also be arranged between the outer dam ODM and the inner dam IDM while being spaced apart from the outer dam ODM.

In this case, the outer dam ODM may be positioned on the third organic film 143, and the touch planarization film 184 may be positioned on the second organic film 142. The touch planarization film 184 between the bending area BA and the outer dam ODM may be arranged to overlap a region where the third organic film 143 is removed and the second organic film 142 is exposed.

In the non-display area NA, the third organic film 143 may be arranged on the second organic film 142 positioned in the bending area BA so as to overlap the bending area BA.

The outer dam ODM may be arranged between the touch planarization film 184 and the inner dam IDM while being spaced apart from the inner dam IDM and the bending area BA. The outer dam ODM may be arranged not to overlap a coating layer 192 positioned in the bending area BA.

The outer dam ODM may be arranged in the same layer as the touch planarization film 184 while being spaced apart from the touch planarization film 184. The outer dam ODM may be arranged in a structure that surrounds the periphery of the touch planarization film 184 while being spaced apart from the touch planarization film 184 that covers the inner dam IDM at the inner side of the outer dam ODM. The touch planarization film 184 arranged adjacent to but not overlapping the bending area at the outer side of the outer dam ODM may be arranged to be spaced apart from the outer dam ODM. Here, the touch planarization film 184 of the non-display area NA may include a first touch planarization film 184a positioned at the inner side of the outer dam ODM and a second touch planarization film 184b positioned at the outer side of the outer dam ODM, and the first touch planarization film 184a and the second touch planarization film 184b may be spaced apart from each other. In this case, the outer dam ODM may be positioned between the first touch planarization film 184a and the second touch planarization film 184b. Here, the first touch planarization film 184a may be the touch planarization film 184 of the non-display area NA formed by extending the touch planarization film 184 of the display area AA into the non-display area NA.

Referring to FIG. 8, the outer dam ODM may have a first width W1 in a direction perpendicular to the bending line BL. The touch planarization film 184 spaced apart from the outer dam ODM and positioned adjacent to the bending area BA at the outer side of the outer dam ODM may have a second width W2 in a direction perpendicular to the bending line BL. In this case, the second width W2 of the touch planarization film 184 may be greater than the first width W1 of the outer dam ODM.

The outer dam ODM may be arranged in a patterned shape, so that the periphery of the outer dam ODM may correspond to a step-generation region, where a bending stress may be concentrated in or transferred from the bending area BA. When the touch planarization film 184 having the second width W2 greater than the first width W1 of the outer dam ODM is positioned between the outer dam ODM and the bending area BA as in the present specification, the bending stress may be prevented or reduced from being transferred and concentrated around the outer dam ODM, thereby preventing or reducing the application of the bending stress. Accordingly, the display device 100 according to the present specification may prevent or reduce cracks in the wires or films around the bending area BA that may be caused by bending.

Trenches T1 and T2 may be provided in a space between the outer dam ODM and the touch planarization films 184 on opposite sides of the outer dam ODM. Specifically, a first trench T1 may be positioned between the outer dam ODM and the touch planarization film 184 at the inner side of the outer dam ODM, and a second trench T2 may be positioned between the outer dam ODM and the touch planarization film 184 at the outer side of the outer dam ODM.

The first trench T1 may be formed as the touch planarization film 184 between the outer dam ODM and the inner dam IDM is spaced apart from the outer dam ODM, and the second trench T2 may be formed as the touch planarization film 184 between the outer dam ODM and the bending area BA is spaced apart from the outer dam ODM.

The first trench T1 between the outer dam ODM and the touch planarization film 184 at the inner side may be arranged on four sides of the non-display area NA surrounding the display area AA. The second trench T2, which is positioned closer to the bending area BA than the first trench T1, may be arranged in a direction parallel to the bending line BL or in a direction along the bending line BL.

The first trench T1 may have a first distance D1 which is a separation distance between the touch planarization film 184 and the outer dam ODM, and the second trench T2 may have a second distance D2 which is a separation distance between the touch planarization film 184 and the outer dam ODM. In this case, the second distance D2 may be greater than the first distance D1, but is not limited thereto. For example, the first distance D1 and the second distance D2 may be the same.

The depth of the first trench T1 and the depth of the second trench T2 may be the same.

The touch insulating film 183 may be exposed by the first and second trenches T1 and T2. Specifically, the first trench T1 and the second trench T2 may penetrate the touch planarization film 184 to expose the touch insulating film 183 positioned below the outer dam ODM.

The touch insulating film 183 may include a material different from that of the outer dam ODM or the touch planarization film 184. For example, the outer dam ODM and the touch planarization film 184 may be configured to include an organic material, and the touch insulating film 183 may be configured to include an inorganic material, but the present disclosure is not limited thereto.

The overflow of the protective film 186 of the touch member 180 may be controlled by the outer dam ODM, and the touch insulating film 183 exposed in the first trench T1 may be made of a different material from the touch planarization film 184 or the outer dam ODM, thereby increasing the surface energy difference or surface resistance. This may effectively control the flow of the protective film 186 of the touch member 180, and allow the protective film 186 to be confined within the first trench T1.

The outer dam ODM may be arranged in an embossed protruding pattern with respect to the substrate 111. A chemical material used during the patterning process of the outer dam ODM may remain in a relatively high amount around the outer dam ODM. If an organic film is positioned below the outer dam ODM, the remaining chemical material easily degrades the organic film, increasing the likelihood of crack formation in the organic film. However, the display device 100 according to the present specification exposes the touch insulating film 183 of an inorganic material through the first trench T1 and the second trench T2 positioned on opposite sides of the outer dam ODM, preventing or reducing film degradation even if the chemical material remains, thereby minimizing or reducing crack formation, and improving the reliability of the display device 100.

The second trench T2 between the outer dam ODM and the touch planarization film 184 may be arranged to overlap the optical member 90. The second trench T2 may be filled with the optical member 90 or an optical adhesive material of the optical member 90. The optical member 90 or the optical adhesive material of the optical member 90 may be relatively thicker than the outer dam ODM.

The outer dam ODM according to the present specification may be arranged to be spaced apart from the bending area BA and to overlap the optical member 90, and the second trench T2 between the outer dam ODM and the touch planarization film 184 may be filled with a material constituting the optical member 90 having a relatively greater thickness. The second trench T2 between the outer dam ODM and the touch planarization film 184 may be filled with a material constituting the optical member 90 having a relatively large thickness to absorb the stress applied to the substrate 111 or the display panel 110 due to bending, thereby preventing or reducing deformation of the display device 100.

The outer dam ODM may include the same material and/or may be positioned in the same layer as the touch planarization film 184 positioned in the display area AA. The outer dam ODM and the touch planarization film 184 may include the same organic material. The outer dam ODM may include a polymer such as silicon oxycarbon (SiOCz), epoxy, polyimide, acrylate, or polyethylene-based material, but is not limited thereto.

The inner dam IDM may include the same material and/or may be positioned in the same layer as the organic film 140 positioned in the display area AA.

When the inner dam IDM positioned in the non-display area NA is positioned using the same material and/or in the same layer as the second organic film 142 of the organic film 140 and the third organic film 143 of the display area AA, or the outer dam ODM positioned in the non-display area NA is positioned using the same material and/or in the same layer as the touch planarization film 184 positioned in the display area AA, additional process steps may be reduced. Therefore, the display device 100 according to the present specification may reduce greenhouse gases that may be generated during the manufacturing process through process optimization, thereby implementing Environment/Social/Governance (ESG).

Referring back to FIG. 6, the optical member 90 may be positioned on the protective film 186 of the touch member 180. The optical member 90 may be referred to as a polarizing plate. The optical member 90 may overlap the display area AA of the display panel 110 and may be arranged to correspond to the entire display area AA. The optical member 90 may be positioned between the cover member 20 and the display panel 110 as shown in FIG. 2. The optical member 90 may include an adhesive layer (not shown), and may be attached to the rear surface of the cover member 20 by the adhesive layer positioned on the top surface thereof.

The optical member 90 may be positioned on the display panel 110 and may block light incident from the outside from being reflected by the electrode and wires positioned in the panel 30 and the touch line TL positioned in the touch member 180 and being emitted as reflected light.

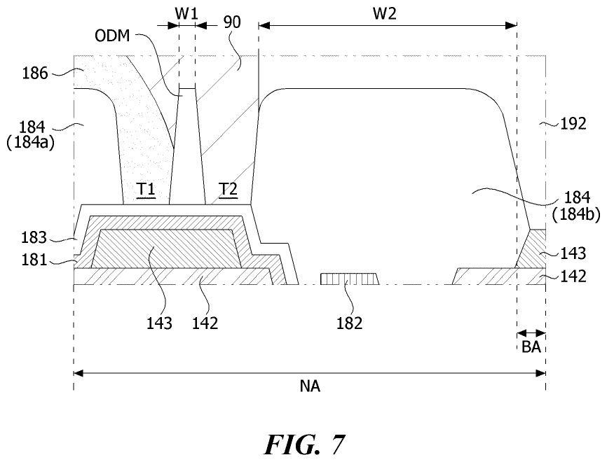

As shown in FIGS. 6 and 7, the optical member 90 may be arranged to overlap at least a portion of the non-display area NA to cover the outer dam ODM and the second trench T2. The optical member 90 may be positioned on the protective film 186 of the touch member 180 in the non-display area NA, and may be arranged to entirely cover the protective film 186 of the touch member 180.

The optical member 90 may extend to the inner region of the touch planarization film 184 positioned between the outer dam ODM and the bending area BA in the non-display area NA. The optical member 90 may be arranged to be in contact with at least a portion of the inner side surface of the touch planarization film 184 positioned between the outer dam ODM and the bending area BA, and not to overlap the top surface of the touch planarization film 184 positioned between the outer dam ODM and the bending area BA.

The edge of the optical member 90 in the non-display area NA may be in contact with the coating layer 192. The contact portion between the optical member 90 and the coating layer 192 may be located between the outer dam ODM and the touch planarization film 184 at the outer side. The optical member 90 and the coating layer 192 may be in contact with each other on the touch planarization film 184 located at the outer side of the outer dam ODM.

The coating layer 192 may be positioned in the bending area BA to prevent or reduce bending stress generated in the bending area BA from being transferred to the periphery.

The coating layer 192 may be arranged to overlap the touch planarization film 184 positioned between the outer dam ODM and the bending area BA. The coating layer 192 may be arranged such that it is not in contact with the top surface of the outer dam ODM but is in contact with the top surface of the touch planarization film 184 positioned between the outer dam ODM and the bending area BA.

As shown in FIG. 6, the back plate 31 may be positioned on the rear surface of the substrate 111. The back plate 31 may allow the substrate 111 to remain flat and supports the substrate 111. The back plate 31 may be attached to the rear surface of the substrate 111 through an adhesive (not shown) or the like. The back plate 31 may be arranged to overlap the display area AA while not overlapping the bending area BA.

The back plate 31 may have a certain strength and thickness to compensate for the rigidity of the substrate 111, and may be positioned on the rear surface of the substrate 111. The back plate 31 may include a plastic thin film having rigidity. For example, the back plate 31 may include one of polyethylene terephthalate (PET), polyimide (PI), and polyethylene naphthalate (PEN), without limited thereto.

The outer dam ODM is required to control the flow of the protective film 186 of the touch member 180, and in the display device 100 according to the present specification, the outer dam ODM may be positioned on the touch insulating film 183 so as to increase the resistance of the surface energy barrier against the spreading direction of the protective film 186 of the touch member 180, thereby effectively controlling the flow of the protective film 186 of the touch member 180 through a difference in surface energy or an increase in surface resistance, improving the durability of the display panel 110 and/or preventing or reducing the occurrence of deformation or defects in the display device 100.

In addition, in the display device 100 according to the present specification, the first trench T1 around the outer dam ODM may be filled with the protective film 186 having a relatively large thickness of the touch member 180, the second trench T2 may be filled with the optical member 90 having a relatively large thickness, and the connection portion TP of the wires connected to the bending area BA may be filled with the touch planarization film 184, thereby maintaining a robust structure and/or minimizing or reducing crack formation.

In addition, in the display device 100 according to the present specification, the touch planarization film 184 having a width greater than that of the outer dam ODM may be arranged between the outer dam ODM and the bending area BA, where bending stress may be relatively concentrated, to prevent or reduce bending stress or strain from being concentrated or transferred to the periphery of the outer dam ODM, thereby minimizing or reducing crack formation and improving the reliability of the display device 100.

The present specification may prevent or reduce the occurrence of relative defects by improving the reliability of the display device 100, thereby preventing or reducing the use of harmful production materials or regulatory substances for producing the display device 100, which may be advantageous for recycling and may approach the realization of the environmentally friendly display device 100.

Although the above has been described with reference to the embodiments, these are only examples and do not limit the present disclosure, and the present specification described above is not limited to the above-described embodiments and the accompanying drawings, and the features, structures, effects, and the like exemplified in each embodiment may be implemented by being combined or modified. Accordingly, the contents relating to such combinations and modifications should be construed as being included within the scope of the present disclosure.

### LIST OF REFERENCE NUMBERS

10: Bottom member
20: Cover member
30: Panel
90: Optical member
100: Display device
110: Display panel
111: Substrate
120: Insulating film
121: First insulating film
122: Second insulating film
123: Third insulation Film
131: Connection wire
135: Light-emitting element
140: Organic film
141: First organic layer
142: Second organic layer
143: Third organic layer
150: Encapsulation layer
151: First encapsulation layer
152: Second encapsulation layer
154: Organic encapsulation layer
180: Touch member
181: First touch line
182: Second touch line
183: Touch insulation film
184: Touch planarization film
186: Protective film
192: Coating layer
BA: Bending area
BL: Bending line
IDM: Inner dam
ODM: Outer dam
T1: First trench
T2: Second trench
TL: Touch line
TP: Connection portion

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a display area and a non-display area including a bending area;
an encapsulation layer on the display area and the non-display area;
an inner dam in contact with the encapsulation layer in the non-display area;
a touch member at least partially on the encapsulation layer and the inner dam, and including a touch line, a touch insulating film, a touch planarization film, and a protective film on the touch planarization film; and
an outer dam in contact with the protective film of the touch member at an outer side of the inner dam, and having a first width,
wherein the touch planarization film is spaced apart from the outer dam between the outer dam and the bending area.

2. The display device of claim 1, wherein the touch planarization film is arranged to be adjacent to a bending line of the bending area at an outer side of the outer dam.

3. The display device of claim 1, wherein the outer dam surrounds the inner dam and is in contact with four sides of the protective film of the touch member positioned in the non-display area.

4. The display device of claim 1, wherein the touch planarization film between the outer dam and the bending area is arranged to surround the outer dam and to overlap a connection portion for enabling the touch line adjacent to the bending area to be electrically connected beyond the bending area and the touch planarization film has a second width greater than the first width.

5. The display device of claim 1, further comprising:
a first trench formed by the touch planarization film between the outer dam and the inner dam being spaced apart from the outer dam, and
a second trench formed by the touch planarization film between the outer dam and the bending area being spaced apart from the outer dam,
wherein the first trench is arranged on four sides of the non-display area surrounding the display area.

6. The display device of claim 5, wherein the first trench has a first distance by which the touch planarization film is spaced apart from the outer dam, the second trench has a second distance by which the touch planarization film is spaced apart from the outer dam, and the second distance is greater than the first distance.

7. The display device of claim 5, wherein a depth of the first trench and a depth of the second trench are the same.

8. The display device of claim 5, wherein the first trench and the second trench penetrate the touch planarization film to expose the touch insulating film positioned below the outer dam, and the touch insulating film includes an inorganic material.

9. The display device of claim 5, further comprising:
an optical member on the touch member; and
a coating layer positioned in the bending area,
wherein the outer dam overlaps the optical member, and the touch planarization film positioned between the outer dam and the bending area overlaps the coating layer.

10. The display device of claim 9, wherein the optical member and the coating layer are in contact with each other on the touch planarization film positioned adjacent to the bending area at the outer side of the outer dam.

11. The display device of claim 9, wherein at least a portion of the first trench is filled with the protective film of the touch member, and the second trench is filled with at least a portion of the optical member.

12. The display device of claim 9, wherein a top surface of the outer dam is in contact with the optical member, and a top surface of the touch planarization film positioned between the outer dam and the bending area is in contact with the coating layer.

13. The display device of claim 1, wherein the outer dam and the touch planarization film include a same organic material.

14. The display device of claim 1, wherein the touch line includes a first touch line and a second touch line arranged with the touch insulating film interposed therebetween,
the touch member further includes a connection wire connected to the first touch line or the second touch line through a connection portion and extending to the bending area, and
an inner groove of the connection portion is filled with the touch planarization film.

15. The display device of claim 1, wherein the encapsulation layer includes a first encapsulation layer made of an inorganic material, an organic encapsulation layer made of an organic material, and a second encapsulation layer,
the encapsulation layer overlaps the inner dam and does not overlap the bending area,
the protective film of the touch member on the encapsulation layer at least partially overlaps the inner dam and the outer dam, and does not overlap the touch planarization film positioned adjacent to a bending line of the bending area.

16. The display device of claim 15, wherein the inner dam is in contact with the organic encapsulation layer, and the outer dam and the touch planarization film positioned adjacent to the bending line are not in contact with the organic encapsulation layer.

17. The display device of claim 1, wherein the inner dam includes the same material as an organic film of the display area positioned below the encapsulation layer, and
the outer dam includes the same material as the touch planarization film positioned above the encapsulation layer in the display area and positioned adjacent to a boundary of the bending area in the non-display area.

18. The display device of claim 1, wherein the inner dam controls a flow of the encapsulation layer, and the outer dam controls a flow of the protective film of the touch member positioned on the encapsulation layer.

19. The display device of claim 1, further comprising:
a connection wire including a connection portion in contact with the touch line,
wherein the connection portion overlaps the touch planarization film positioned between the outer dam and the bending area so as to surround the outer dam.

20. The display device of claim 1, wherein the touch planarization film includes a first touch planarization film extending from the display area to the non-display area and a second touch planarization film spaced apart from the first touch planarization film,
the outer dam is arranged between the first touch planarization film and the second touch planarization film while being spaced apart therefrom such that a first trench and a second trench are formed, and
the first trench is arranged on four sides of the non-display area surrounding the display area.
